(19) United States
(12) Patent Application Publication
(10) Pub. No.: US 2013/0049844 A1
(43) Pub. Date: Feb. 28, 2013

(54) CAPACITIVE TOUCH SENSOR HAVING LIGHT SHIELDING STRUCTURES

(71) Applicants: Ion Bita, San Jose, CA (US); Leonard Eugene Fennell, Foster City, CA (US); William J. Cummings, Clinton, WA (US)

(72) Inventors: Ion Bita, San Jose, CA (US); Leonard Eugene Fennell, Foster City, CA (US); William J. Cummings, Clinton, WA (US)

(73) Assignee: QUALCOMM MEMS Technologies, Inc., San Diego, CA (US)

(21) Appl. No.: 13/216,060

(22) Filed: Aug. 23, 2011

(51) Int. Cl. H03K 17/96; G01R 31/28; H05K 13/00

(52) U.S. Cl. 327/517; 29/592.1; 29/593

(57) ABSTRACT

This disclosure provides systems, methods, and apparatus related to a capacitive touch sensor with light shielding structures. In one aspect, a device includes an array formed by a plurality of row electrodes and a plurality of non-transparent column electrodes, wherein at least a first portion of the row electrodes is non-transparent and coplanar with the column electrodes and at least a second portion of the row electrodes is non-coplanar with the column electrodes. The device further includes light shielding structures that are non-transparent and coplanar with the column electrodes, wherein the light shielding structures substantially overlap the second portion.

### TECHNICAL FIELD

This disclosure relates to capacitive touch sensors.

### DESCRIPTION OF THE RELATED TECHNOLOGY

Electromechanical systems include devices having electrical and mechanical elements, actuators, transducers, sensors, optical components (e.g., minors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

### SUMMARY

The systems, methods and devices of the disclosure each have several innovative aspects, no single one of which is solely responsible for the desirable attributes disclosed herein.

One innovative aspect of the subject matter described in this disclosure can be implemented in a device. In some implementations, the device includes a plurality of non-transparent column electrodes and a plurality of row electrodes. Each of the row electrodes is electrically isolated from each of the column electrodes. At least one of the plurality of row electrodes includes a first portion and a second portion. The first portion is non-coplanar with at least one of the column electrodes and the second portion is non-transparent and non-coplanar with the first portion. The device also includes at least one light shielding structure which overlies at least a portion of the first portion.

In some implementations, the second portion can be non-coplanar with the at least one of the column electrodes. In some implementations, the light shielding structure can be coplanar with the first portion of the at least one row electrode. In some implementations, the plurality of row electrodes and the plurality of column electrodes can extend generally perpendicular to one another. In some implementations, the at least one light shielding structure extends generally parallel to the at least one row electrode.

In some implementations, the at least one light shielding structure can be electrically isolated from the plurality of row electrodes. In some implementations, the at least one light shielding structure can be electrically isolated from the plurality of column electrodes.

In some implementations, the at least one light shielding structure can include a reflective layer, an absorber layer, and at spacer layer located between the reflective layer and the absorber layer. In some implementations, the spacer layer can include a conductive material. In other implementations, the transparent layer can include a dielectric material.

In some implementations, the device can further include a processor configured to apply one or more voltages to a set of row electrodes and measure one or more voltages at a set of column electrodes. The processor can be further configured to determine one or more touch locations based on the measured one or more voltages.

In some implementations, the at least one column electrode overlies the first portion of the at least one row electrode at an intersection. In some implementations, an exposed portion of the first portion can be less than 25 percent of the first portion as a whole. In some implementations, the at least one light shielding structure can overlie the first portion as to prevent the first portion from being visible to a naked eye. In some implementations, the at least one light shielding structure can overlie the first portion as to prevent the first portion from interfering with viewing images displayed by a screen behind the array. In some implementations, the first portion can be transparent.

Another innovative aspect of the subject matter described in this disclosure may be implemented in a method of manufacturing a device. In some implementations, the method includes forming a plurality of row electrodes and a plurality of non-transparent column electrodes. Each of the row electrodes is electrically isolated from each of the column electrodes. At least one of the plurality of row electrodes includes a first portion and a second portion. The first portion is non-coplanar with at least one of the column electrodes and the second portion is non-transparent and non-coplanar with the first portion. The method also includes forming at least one light shielding structure that overlies at least a portion of the first portion.

In some implementations, the method includes coupling a processor to a set of row electrodes and to a second set of column electrodes. The processor may be configured to apply one or more voltages to the set of row electrodes and measure one or more voltages at the set of column electrodes. The processor may also be configured to determine one or more touch locations based on the measured one or more voltages.

In some implementations, forming the at least one light shielding structures can include forming a reflective layer, an absorber layer, and a transparent layer between the reflective layer and the absorber layer.

In some implementations, an exposed portion of the first portion is less than 25 percent of the first portion as a whole. In some implementations, the at least one light shielding structure overlies the first portion as to prevent the second portion from interfering with viewing images displayed by a screen behind the array.

Another innovative aspect of the subject matter describes in this disclosure may be implemented in a device. In some implementations, the device includes a plurality of non-transparent column electrodes and a plurality of row electrodes. Each of the row electrodes is electrically isolated from each of the column electrodes. At least one of the plurality of row electrodes includes a first portion and a second portion. The first portion is non-coplanar with at least one of the column electrodes and the second portion is non-transparent and non-coplanar with the first portion. The device also includes means for shielding light from the first portion.

In some implementations, the means for shielding light can include a reflective layer, an absorber layer, and a spacer layer located between the reflective layer and the absorber layer. In some implementations, the spacer layer includes a conductive material. In some implementations, the spacer layer includes a dielectric material. In some implementations, the means for shielding light can include an absorber.

In some implementations, the device further can include a processor configured to apply one or more voltages to a set of row electrodes, for measuring one or more voltages at a set of column electrodes. The processor can also determine one or more touch locations based on the measured one or more voltages.

In some implementations, the at least one column electrode overlies the first portion of the at least one row electrode at an intersection. In some implementations an exposed portion of the first portion is less than 25 percent of the first portion as a whole. In some implementations, the means for shielding light overlie the first portion as to prevent the first portion from being visible to a naked eye. In some implementations, the means for shielding light overlie the first portion as to prevent the first portion from interfering with viewing images displayed by a screen behind the array.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIG. 9 shows an example of a diagram of a projected capacitive touch (PCT) sensor.

FIG. 10 shows an example of a circuit diagram of the PCT sensor of FIG. 9.

FIG. 11 shows an example of a diagram of a PCT sensor having row electrodes that are partially coplanar and partially non-coplanar with column electrodes.

FIG. 12A shows a top view of an example of an intersection of a PCT sensor with light shielding structures coupled to the row electrode.

FIG. 12B shows a cross-sectional view of the intersection of the PCT sensor of FIG. 12A taken along line 12B-12B.

FIG. 12C shows a top perspective view of the intersection of the PCT sensor of FIG. 12A.

FIG. 13A shows a top view of an example of an intersection of a PCT sensor with light shielding structures coupled to the column electrode.

FIG. 13B shows a cross-sectional view of the intersection of the PCT sensor of FIG. 13A taken along line 13B-13B.

FIG. 13C shows a top perspective view of the intersection of the PCT sensor of FIG. 13A.

FIG. 14A shows a top view of an example of an intersection of a PCT sensor with light shielding structures uncoupled from both the row electrode and the column electrode.

FIG. 14B shows a cross-sectional view of the intersection of the PCT sensor of FIG. 14A taken along line 14B-14B.

FIG. 14C shows a top perspective view of the intersection of the PCT sensor of FIG. 14A.

FIG. 15 shows an example of a cross-section of an interferometric stack that absorbs visible light.

FIG. 16 shows an example of a flow diagram illustrating a manufacturing process for a PCT sensor.

FIGS. 17A and 17B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

A touchscreen can detect the presence and location of a touch within a display area and display visual information in the display area. In some implementations, a touchscreen can include a projected capacitive touch (PCT) sensor arranged over a display. The PCT sensor can include an array of capacitors formed by a number of sensor electrodes in the form of overlapping electrodes, such as row electrodes and column electrodes that are arranged in a grid pattern. The sensor electrodes may overlap by passing over or under one another at intersections or junctions between, e.g., a row electrode and a column electrode. The overlapping portions of these electrodes are electrically isolated from one another, forming a capacitor at these intersections or junctions. In some implementations, a first portion of a row electrode can be formed on an underlying surface or substrate that extends along a different level or plane as a column electrode during a manufacturing process, e.g., during a thin film deposition process, and thus, the first portion can be considered to be non-coplanar with the column electrode. The first portion of the row electrodes forms part of each capacitor in the array of capacitors of the PCT sensor. Additionally, a second portion of the row electrode can be formed on the same level or plane as the column electrode such that the first portion and the second portion are offset from one another. Thus, the second portion can be considered to be coplanar with the column electrode. However, the non-coplanar first portion of the row electrode can electrically connect the coplanar second portion of the row electrode with another portion that is coplanar with the column electrode such that the row electrode is physically separated, and electrically isolated, from the column electrode. The non-coplanar portion of the row electrode can include a non-transparent reflective material, for example, a metal, which may reflect light toward a user of the touchscreen and thereby negatively affect the viewing of the underlying display through the PCT sensor. In some implementations, the PCT sensor can further include one or more light shielding structures that are non-transparent and coplanar with the column electrodes. The light shielding structures can substantially overlap and/or cover the non-coplanar portions of the row electrodes and thereby shield them from view. Therefore, the light shielding structures can limit the reflectance from the non-coplanar portions of the row electrodes and enhance the display of images viewed through the PCT sensor (e.g., enhance a contrast characteristic of the touchscreen). The column electrodes and coplanar portions of the row electrodes may also include such light shielding structures.

Particular implementations of the subject matter described in this disclosure can be implemented to realize one or more of the following potential advantages. In some implementations, light shielding structures substantially overlap reflective portions of the electrodes (e.g., row electrodes or column electrodes) of a touchscreen to shield a substantial portion of the reflective portions from a user. Because reflections from sensor electrodes can affect the overall contrast of a touchscreen, the light shielding structures can improve the visual performance of the touchscreen by limiting an amount of light that is reflected by the reflective portions towards a user.

An example of a suitable EMS or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

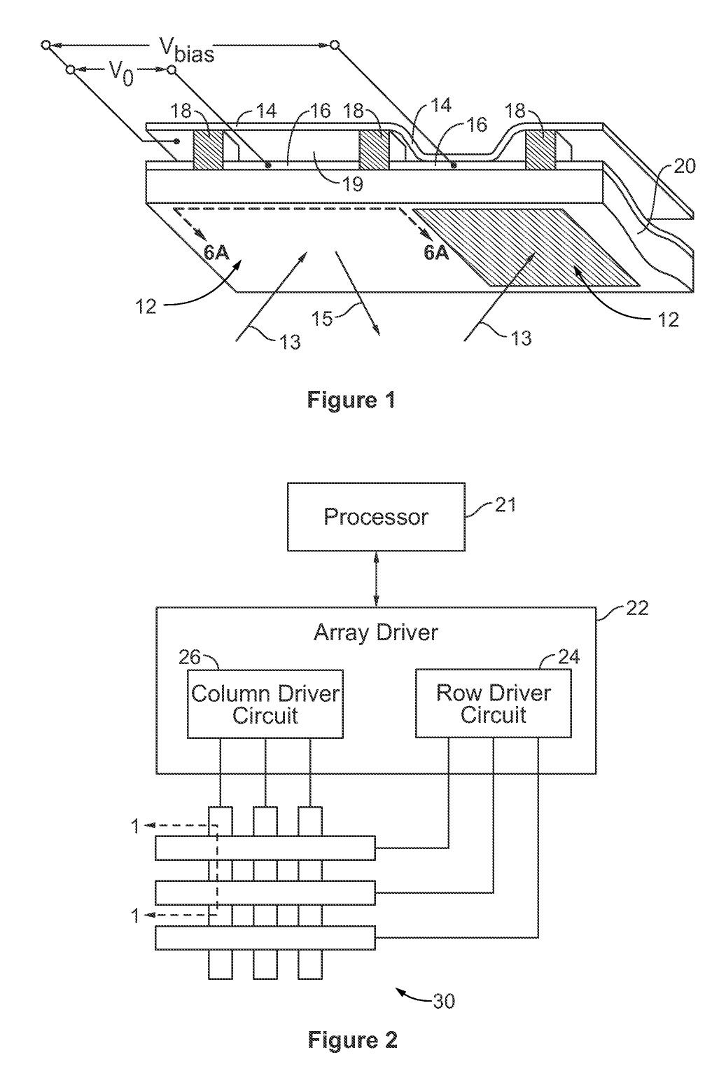

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be approximately 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

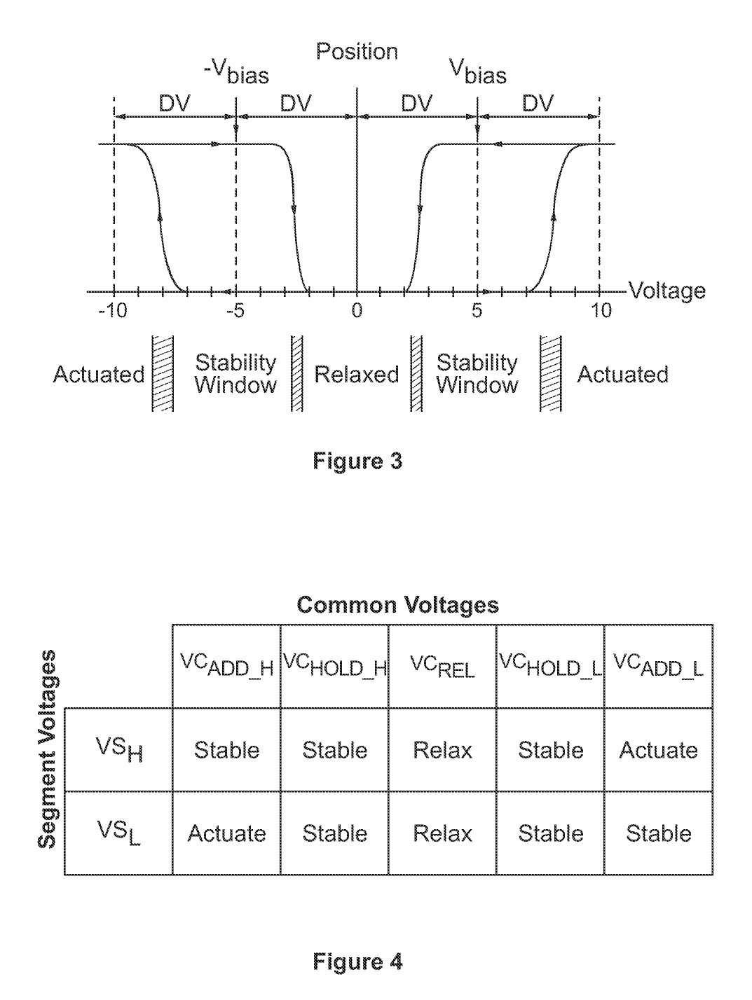

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

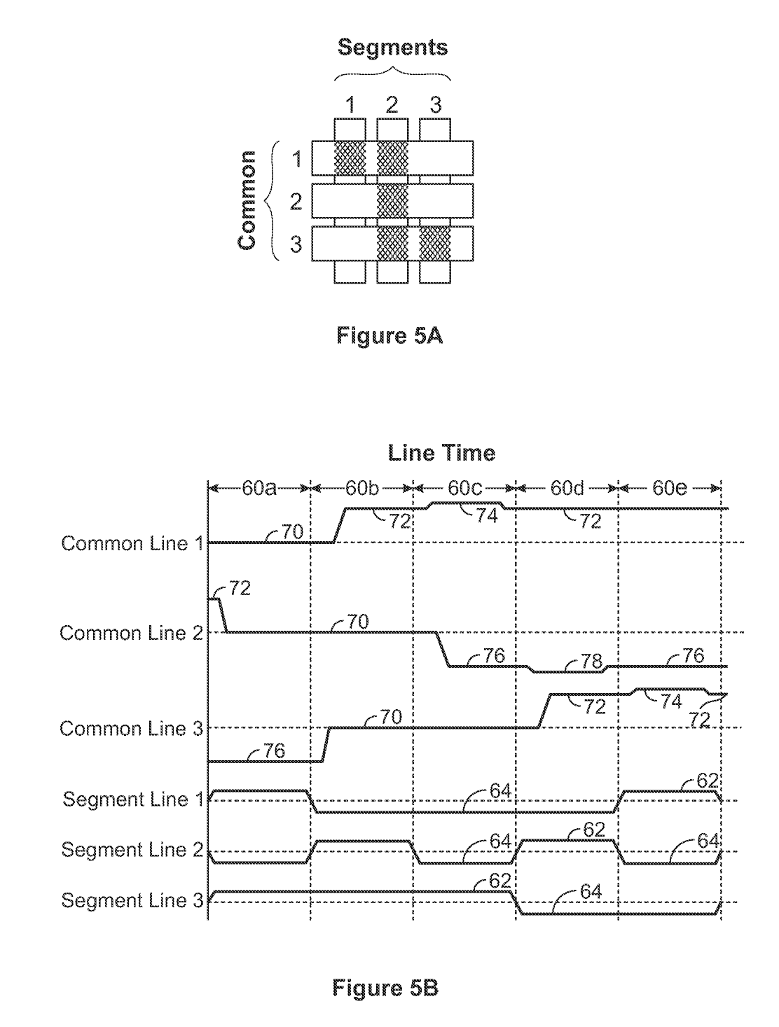

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or minor, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

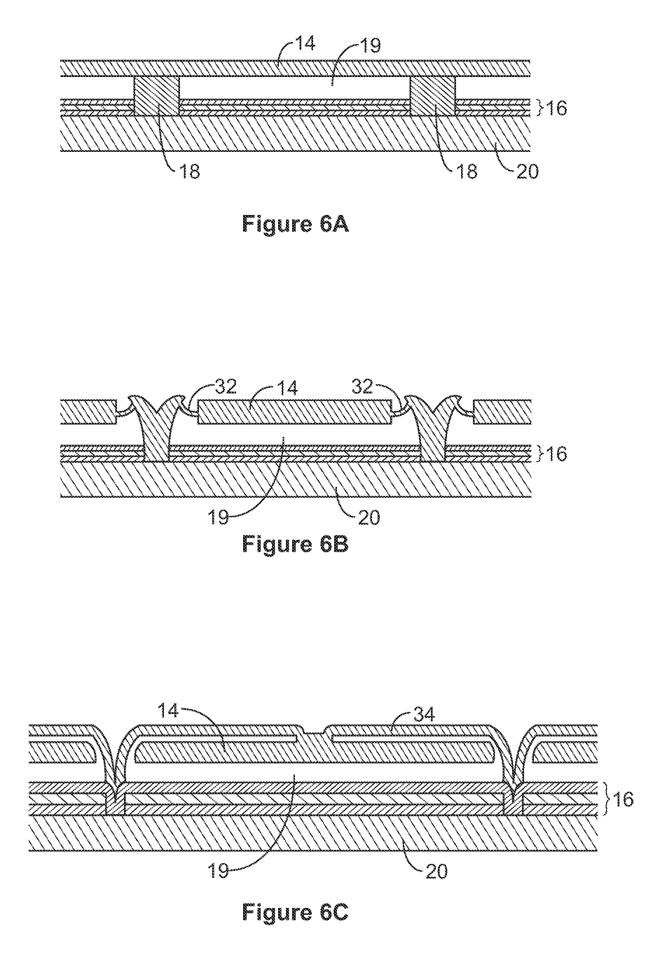

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

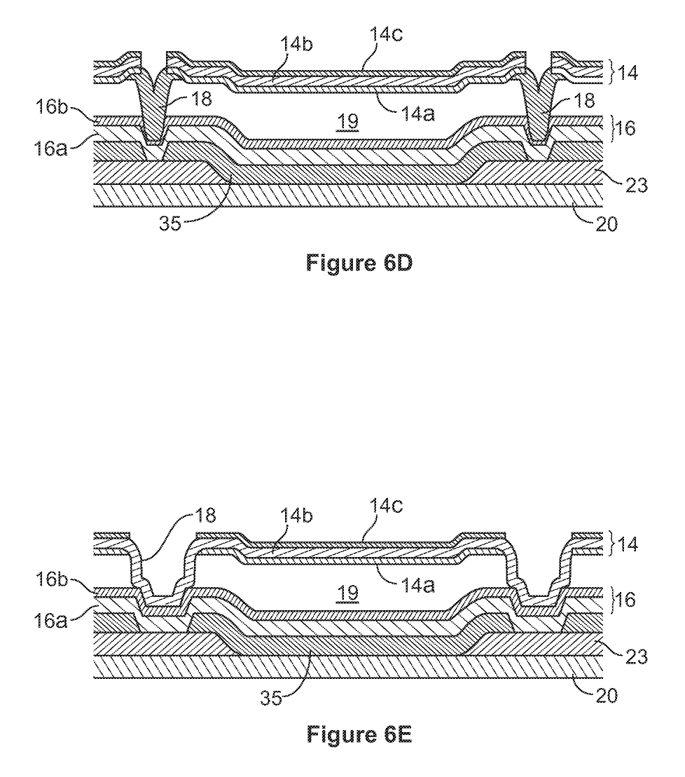

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}-relax and VC_{HOLD}_{_{—}}_{L}-stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

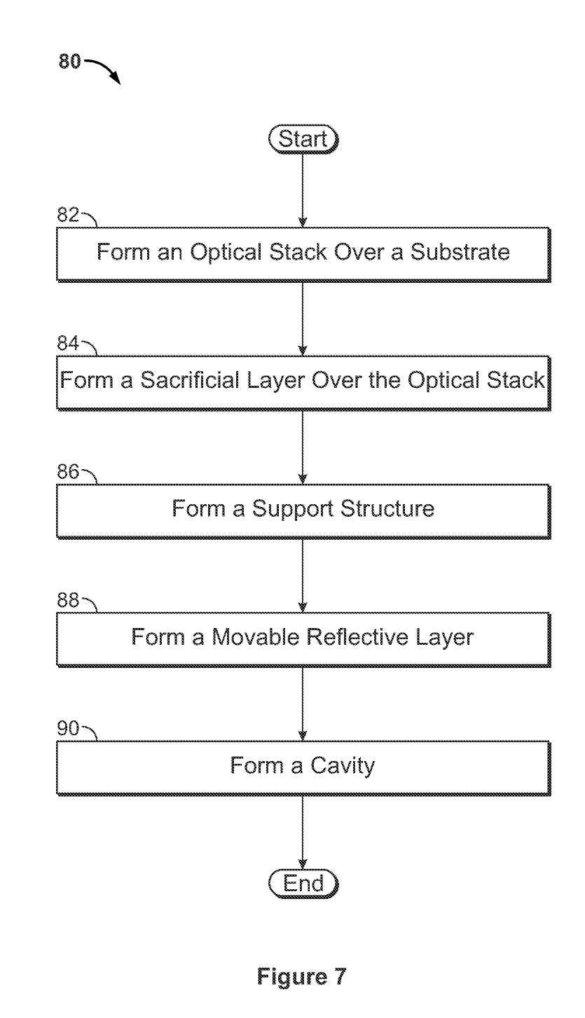

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 14a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a spacer layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoromethane (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

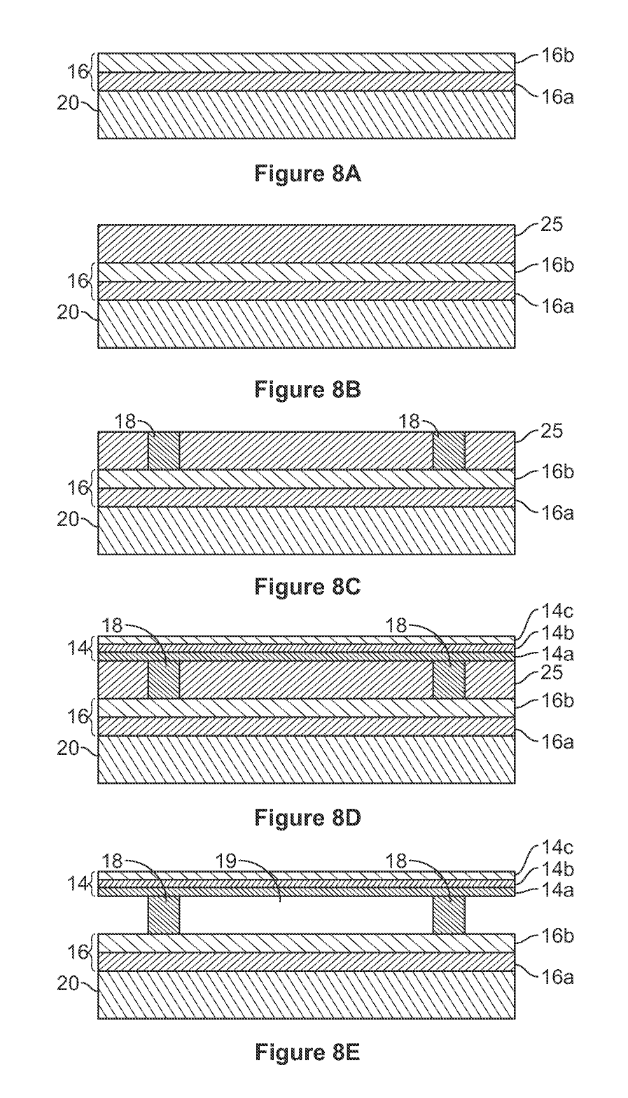

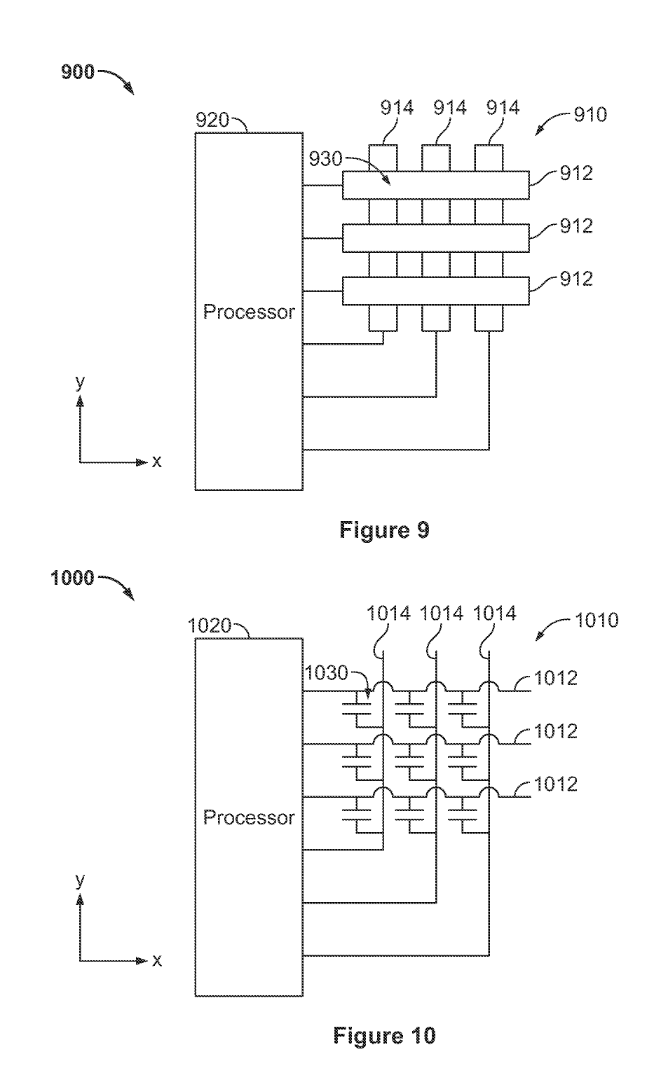

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

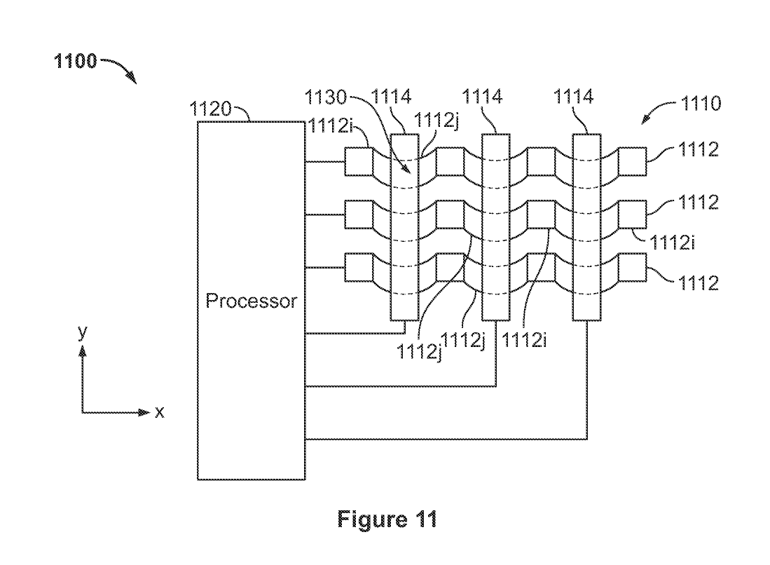

To assist in the description of the features described below with reference to FIGS. 9-15, the following Cartesian coordinate terms are used, consistent with the coordinate axes illustrated in FIGS. 9-15. An “x-axis” extends perpendicular to a “y-axis” and a “z-axis.” The y-axis and the z-axis extend perpendicular to each other. Thus, the z-axis is orthogonal to a plane formed by the x-axis and the y-axis. Further, although structures disclosed herein, e.g., row electrodes, column electrodes, and/or light shielding structures, may be generally described as “coplanar” with respect to other structures, and/or non-coplanar with respect to other structures, it will be understood that these structures may themselves be contoured. As such, references to non-coplanar structures will be understood to mean that these structures are transversely offset of spaced apart from one another to allow for electrical isolation.

FIG. 9 shows an example of a diagram of a projected capacitive touch (PCT) sensor 900. The sensor 900 may be placed over a display panel or display device to form a touchscreen. As discussed above, a touchscreen can detect the presence and location of a touch within a display area of the display device. In some implementations, the sensor 900 includes a number of sensor electrodes, namely, a number of row electrodes 912 and a number of column electrodes 914. The row electrodes 912 are positioned over and generally perpendicular to the column electrodes 914 to form a capacitor grid 910. As illustrated, the row electrodes 912 can form line segments that extend parallel to one another. That is to say, the row electrodes 912 can extend in a substantially linear direction. Similarly, the column electrodes 914 can also extend in a substantially linear direction generally perpendicular to the row electrodes 912 forming an array or grid. In some implementations, at least a portion of the row electrodes 912 can extend underneath the column electrodes 914 to form the capacitor grid 910. The row electrodes 912 and the column electrodes 914 can include various conductive materials including, for example, transparent conductive oxides and non-transparent reflective metals. In some implementations, the row electrodes 912 and the column electrodes 914 can include the same materials. In other implementations, the row electrodes 912 and the column electrodes 914 can include different materials.

In some implementations, each of the row electrodes 912 and column electrodes 914 are coupled to a processor 920. The processor 920 can be configured to apply a voltage to the row electrodes 912 and to measure a voltage at the column electrodes 914 or vice versa. A location where a portion of the row electrodes 912 overlaps (e.g., by passing above or below) a portion of the column electrodes 914 can be referred to as an intersection or junction 930. The row electrodes 912 are at least partially offset along the z-axis (out of the page) from the column electrodes 914 at least at intersections 930. Stated differently, at least a portion of the row electrodes 912 is formed on a first plane that extends parallel to the x-y plane, the column electrodes 914 are formed on a second plane that extends parallel to the x-y plane, and the first plane and the second plane are offset or spaced apart from one another. Thus, at least a portion of the row electrodes 912 and the column electrodes 914 can be formed during separate thin film deposition processes, resulting in the portion of the row electrodes 912 and the column electrodes 914 being on different planes. For example, the row electrodes 912 can be disposed at least partially above the column electrodes 914 as schematically depicted in FIG. 9.

Due to this configuration, the row electrodes 912 and the column electrodes 914 do not touch or contact one another at the intersections 930. Thus, the row electrodes 912 and the column electrodes 914 can at least partially overlap to form capacitors at the intersections 930. In some implementations, such an insulating layer can be substantially transparent and/or light transmissive to allow visible light to pass therethrough. As discussed in further detail below, an insulating layer can be disposed between the column electrodes 914 and the row electrodes 912 to maintain an insulating space therebetween, electrically isolating the row electrodes 912 from the column electrodes 914.

When a conductive input device, such as stylus or a finger, is brought close to one or more of the intersections 930, the electrostatic field at those locations is changed altering the capacitance of the capacitors formed at the intersections 930. The capacitance change at each of the intersections 930 can be measured by the row electrodes 912, the column electrodes 914, and the processor 920. Further, the processor 920 can determine the touch location or multiple touch locations based on the measured capacitance changes.

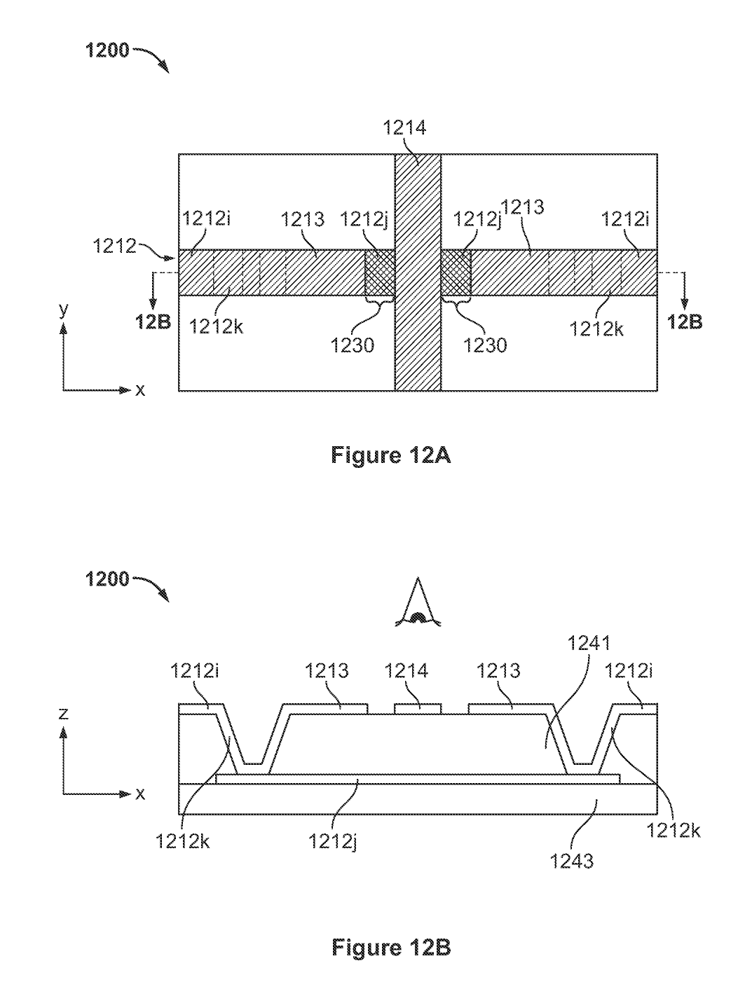

FIG. 10 shows an example of a circuit diagram 1000 of the PCT sensor 900 of FIG. 9. The circuit diagram 1000 illustrates a capacitor grid 1010 having a number of row leads 1012 and column leads 1014 coupled to a processor 1020. The processor 1020 can be configured to apply a voltage to the row leads 1012 and measure a voltage at the column leads 1014 or vice versa. The capacitor grid 1010 includes a two-dimensional array of capacitors 1030, each formed by overlapping portions of one of the row leads 1012 and one of the column leads 1014 such as the intersections 930 of FIG. 9.

As mentioned above with respect to FIG. 9, at least a portion of the row leads 1012 are spaced apart along the z-axis (out of the page) from the column leads 1014. However, in some implementations, other portions of the row leads 1012 may be coplanar with, or formed on the same plane or level as, the column leads 1014. These portions may be connected with jumpers or interconnects which are not coplanar with the column leads 1014 in order to cross over the column leads 1014 while remaining electrically isolated from them.

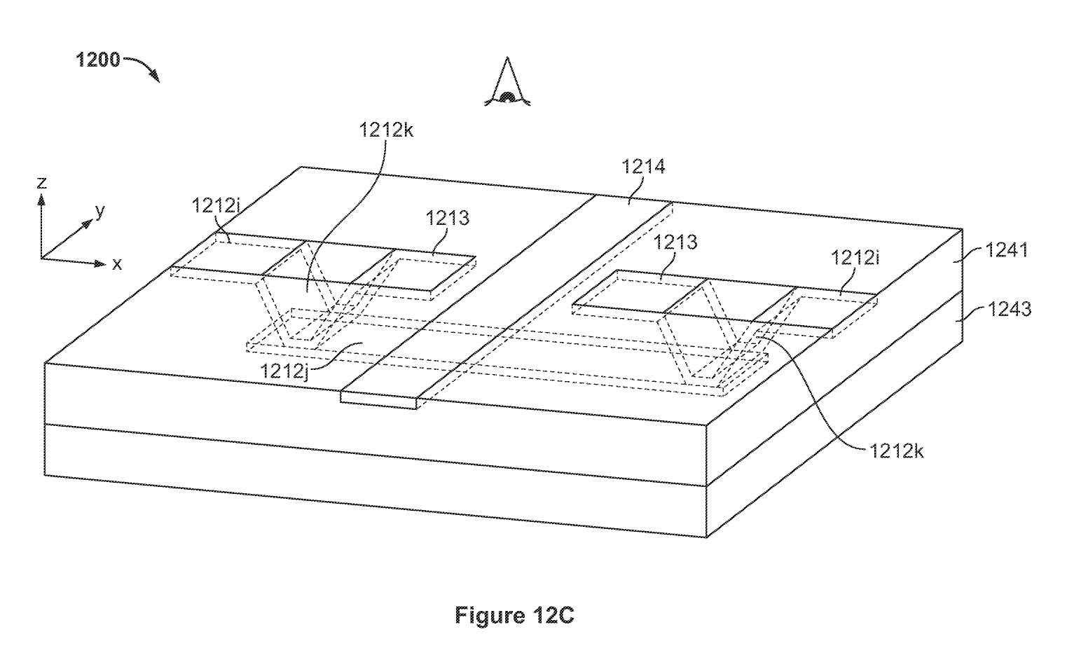

FIG. 11 shows an example of a diagram of a PCT sensor 1100 having row electrodes 1112 that are partially coplanar and partially non-coplanar with column electrodes 1114. Like the sensor 900 of FIG. 9, the sensor 1100 includes a capacitor grid 1110 formed from row electrodes 1112 which are positioned under, and extend generally perpendicular to, column electrodes 1114. Each of the row electrodes 1112 and column electrodes 1114 are coupled to a processor 1120.

The row electrodes 1112 include coplanar portions 1112i and jumper portions 1112j. In the illustrated implementation, the coplanar portions 1112i are coplanar with one another and also generally coplanar with the column electrodes 1114. In contrast, the jumper portions 1112j are non-coplanar or spaced apart along the z-axis (out of the page) from the column electrodes 1114 at least at intersections 1130, such that the overlapping portions of the jumper portions 1112j and the column electrodes 1114 form capacitors at intersections 1130.

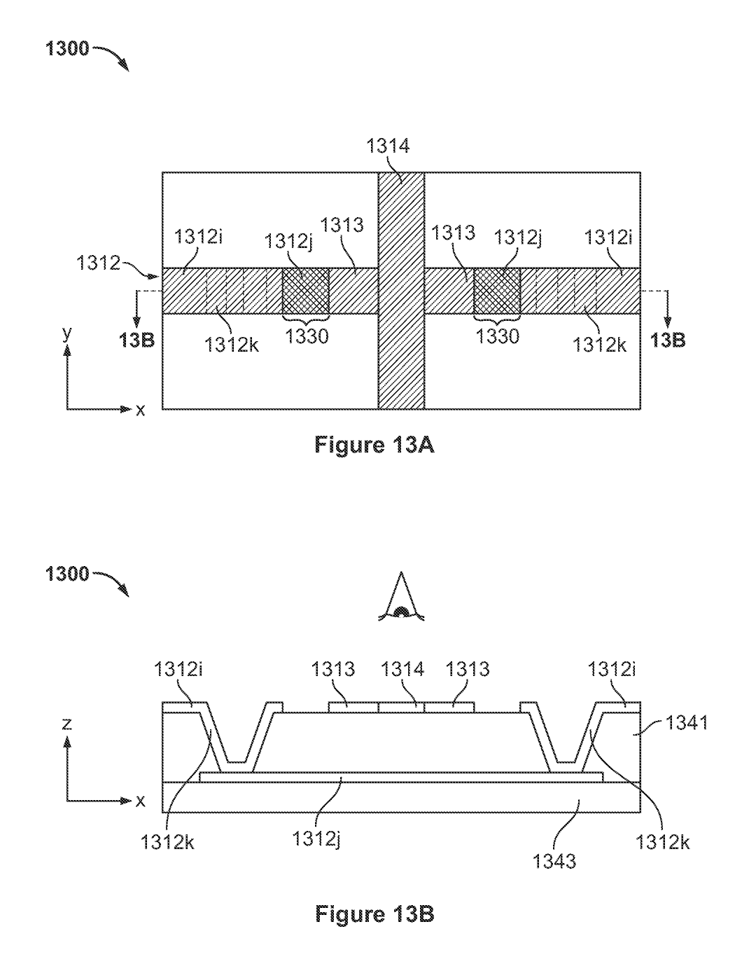

Although FIG. 11 generally shows the jumper portions 1112j as arcuate-shaped curves (e.g., rainbow-shaped curves), other configurations are possible. For instance, the jumper portions 1112j may be U-shaped or staple-shaped. The shape and/or configuration of the jumper portions 1112j may be dictated at least in part by the manufacturing process(es) used to form the PCT sensor 1110. In some implementations, such as the implementations described below with respect to FIGS. 12-14, the jumper portion 1112j may include a generally planar jumper portion 1312j, 1412j, 1512j, coupled to the row electrode by vias or connector portions.

In an implementation in which the column electrodes 1114 and the coplanar portions 1112i of the row electrodes 1112 extend along a common plane, they may advantageously in some implementations be formed at the same time, from the same materials, and/or using the same processes thereby effectuating time and cost savings. The jumper portions 1112j may be formed of any conductive materials. For example, in some implementations, the jumper portions 1112j are metal. However, the metallic appearance of the jumper portions 1112j may be disadvantageous as it may reflect incident light back to a viewer, causing undesirable optical effects. Thus, in some implementations, the jumper portions 1112j are made from a transparent conductive material, such as indium tin oxide (ITO), zinc oxide (ZnO), indium gallium zinc oxide (InGaZnO), etc. In another implementation, the jumper portions 1112j are formed of an interferometric stack that absorbs visible light.

As mentioned above, jumper portions may form part of a row electrode (e.g., a non-planar portion of the row electrode) and serve to interconnect other portions of the row electrode (e.g., coplanar portions of the row electrode on either side of the jumper portion) to prevent electrical coupling of the column electrode and the coplanar portions of the row electrode. Thus, jumper portions can form part of a capacitive sensor electrode (e.g., a row electrode or a column electrode). In some implementations, light shielding structures are formed which overlap the jumper portions and substantially obstruct such jumper portions from the view of a user, allowing the use of a reflective jumper portions, e.g., metallic jumper portions, while reducing the undesirable optical effects resulting from reflections of visible light from the reflective jumper portions. In further implementations, these light shielding structures may be coplanar with either of both of a column electrode or portions of a row electrode.

FIG. 12A shows a top view of an example of an intersection of a PCT sensor 1200 with light shielding structures 1213 coupled to the row electrode 1212. FIG. 12B shows a cross-sectional view of the intersection of the PCT sensor 1200 of FIG. 12A taken along line 12B-12B. FIG. 12C shows a top perspective view of the intersection of the PCT sensor 1200 of FIG. 12A. The sensor 1200 is substantially similar to the sensor 1100 of FIG. 11, but differs in that it includes light shielding structures 1213 which overlie, overlap, or cover at least a portion of underlying jumper portions 1212j. In other words, at least a portion of a light shielding structure 1213 is transversely offset along the z-axis from at least a portion of the a jumper portion 1212j, such that it is disposed over at least the portion of the jumper portion 1212j. The light shielding structures 1213 are configured to absorb visible light incident thereon and/or interferometrically modulate light incident thereon to reflect non-visible wavelengths. In some implementations, the light shielding structures 1213 can include an interferometric stack, e.g., an interferometric black mask. In some implementations, the light shielding structures 1213 can include an absorber, e.g., a black coating and/or layer of absorptive material. In this way, the light shielding structures 1213 can reflect less visible light than reflective structures or materials such as reflective jumper portions 1212j and in some implementations may reflect little or no visible light. In some implementations, the light shielding structures 1213 can be at least partially transparent, e.g., configured to shield or absorb some but not all incident light, and in other implementations, the light shielding structures 1213 can be opaque.

As shown in FIGS. 12B and 12C, coplanar portions 1212i of the row electrode 1212 may be disposed over an insulating dielectric layer 1241 and lie coplanar with the column electrode 1214. The jumper portions 1212j may be disposed over or formed on an underlying substrate layer 1243 that is disposed beneath the insulating layer 1241. Thus, the jumper portions 1212j can be non-coplanar with the coplanar portions 1212i of the row electrodes 1212 and the column electrodes 1214.

The coplanar portions 1212i are electrically connected with the jumper portions 1212j by connection portions 1212k. In some implementations, the connection portions 1212k can be integral or homogeneous with the jumper portions 1212j. Thus, the jumper portions 1212j and the connection portions 1212k can collectively be considered to be non-coplanar portions of the row electrode 1212 because these portions do not lie on the same plane as the coplanar portions 1212i of the row electrode 1212 or the column electrode 1214. Additionally, the light shielding structures 1213 are disposed over the jumper portions 1212j between the connection portions 1212k and the column electrode 1214. In some implementations, the light shielding structures 1213 are coplanar with the column electrode 1214 and the coplanar portions 1212i of the row electrodes 1212. Thus, as shown in FIG. 12A, the light shielding structures 1213 at least partially shield, hide, and/or obstruct the jumper portion 1212j from the view of a user looking at the sensor 1200 from above.

As schematically illustrated in FIG. 12A, the appearance of the light shielding structures 1213 may be similar to the appearances of the column electrode 1214, the connection portions 1212k, and the coplanar portions 1212i of the row electrodes 1212. In other words, the light shielding structures 1213, the column electrode 1214, the connection portions 1212k, and the coplanar portions 1212i of the row electrodes 1212 may each reflect a similar amount of visible light. In some implementations, the column electrode 1214, the connection portions 1212k, the coplanar portions 1212i of the row electrodes 1212, and the light shielding structures 1213 are similarly formed and configured to absorb visible light incident thereon and/or interferometrically modulate light incident thereon to reflect non-visible wavelengths.

As also shown in FIG. 12A, the jumper portions 1212j may have different optical properties than the light shielding structures 1213, the column electrode 1214, the connection portions 1212k, and the coplanar portions 1212i of the row electrodes 1212 when viewed from above. For example, the jumper portions 1212j may reflect more visible light than at least some of the light shielding structures 1213, the column electrode 1214, the connection portions 1212k, and the coplanar portions 1212i of the row electrodes 1212. Because the jumper portions 1212j may be more reflective than the light shielding structures 1213, the column electrode 1214, the connection portions 1212k, and the coplanar portions 1212i of the row electrodes 1212, the light shielding structures 1213 may be disposed between the connection portions 1212k of the row electrodes 1212 and the column electrode 1214 so as to shield a majority of the jumper portion 1212j from view.

With reference now to FIG. 12C, in some implementations, a maximum dimension of the light shielding structures 1213 taken along the y-axis may be greater than a maximum dimension of the jumper portions 1212j taken along the y-axis. In this way, the light shielding structures 1213 can substantially shield the underlying jumper portions 1212j from a viewer even as an angle of view varies. For example, if an angle of view does not extend along the z-axis as illustrated, the greater width or maximum dimension of the light shielding structures 1213 along the y-axis may result in more of the jumper portions 1212j being shielded from the viewer than if the maximum dimensions along the y-axis were the same. As also shown in FIG. 12C, in some implementations the connection portions 1212k may be conformally deposited over a tapered aperture or depression formed in the insulating layer 1241 to interconnect the jumper portions 1212j with the coplanar portions 1212i. Alternatively, in some implementations, the connection portions 1212k may include plugs or vias extending between the jumper portions 1212j and the coplanar portions 1212i. Such plugs or vias may include an overlying mask configured to absorb visible light incident thereon and/or interferometrically modulate light incident thereon to reflect non-visible wavelengths

In some implementations, the light shielding structures 1213 may advantageously be formed at the same time, from the same materials, and/or using the same processes as the column electrodes 1214 (and/or coplanar portions of the row electrodes 1212i) thereby effectuating time and cost savings.

In the implementation illustrated in FIGS. 12A-12C, the light shielding structures 1213 adjacent to a single intersection substantially overlap the jumper portion 1212j of that intersection. The portion of the jumper portion 1212j not covered by the coplanar portion 1212i of the row electrode 1212, the column electrode 1214, and/or the light shielding structures 1213 may be referred to as the exposed jumper portion 1230. The exposed jumper portion 1230 may be characterized as a percentage of the jumper portion 1212j as a whole and this percentage may vary in different implementations, depending on various factors, such as, for example, the sizes, shapes, and locations of the light shielding structures 1213, the row electrodes 1212, and the column electrodes 1214. In some implementations, the exposed jumper portion 1230 may be less than 50% of the jumper portion 1212j as a whole. In some implementations, the exposed jumper portion 1230 may be less than 25% of the jumper portion 1212j as a whole. In some implementations, the exposed jumper portion 1230 may be less than 10% of the jumper portion 1212j as a whole. In some implementations, the exposed jumper portion 1230 may be less than 5% of the jumper portion 1212j as a whole.

In some implementations, the light shielding structures 1213 adjacent to a particular intersection sufficiently cover the jumper portion 1212j of that intersection as to prevent the reflective metal of the jumper portion 1212j from being visible to the naked eye. In other words, the jumper portion 1212j may not be visible to a human without significant magnification (e.g., more than 3× magnification). Because the light shielding structures 1213 can be configured to absorb visible light incident thereon and/or interferometrically modulate light incident thereon to reflect non-visible wavelengths, disposing the light shielding structures 1213 between a viewer and the jumper portions 1212j can prevent the reflective metal of the jumper portion 1212j from interfering with viewing images displayed by a screen or display device disposed beneath the touch sensor.

In some implementations, the light shielding structure 1213 can be generally rectangular and significantly longer in one direction than the other. In some implementations, the length of a light shielding structure 1213 is at least twice the width of the light shielding structure 1213. In some implementations, the length of a light shielding structure 1213 is at least three times the width of the light shielding structure 1213. In some implementations, a length of the light shielding structure 1213 is at least ten times the width of the light shielding structure 1213.

Although FIGS. 12A-12C generally show rectangular light shielding structures 1213, other shapes can be used. For example, the light shielding structures 1213 may be circular, oval, etc. Similarly, although FIGS. 12A-12C generally show a single light shielding structure 1213 on either side of the column electrode 1214 for a particular intersection, in other implementations, there may be multiple, or zero, light shielding structures 1213 on either side of the column electrode 1214 for a particular intersection.

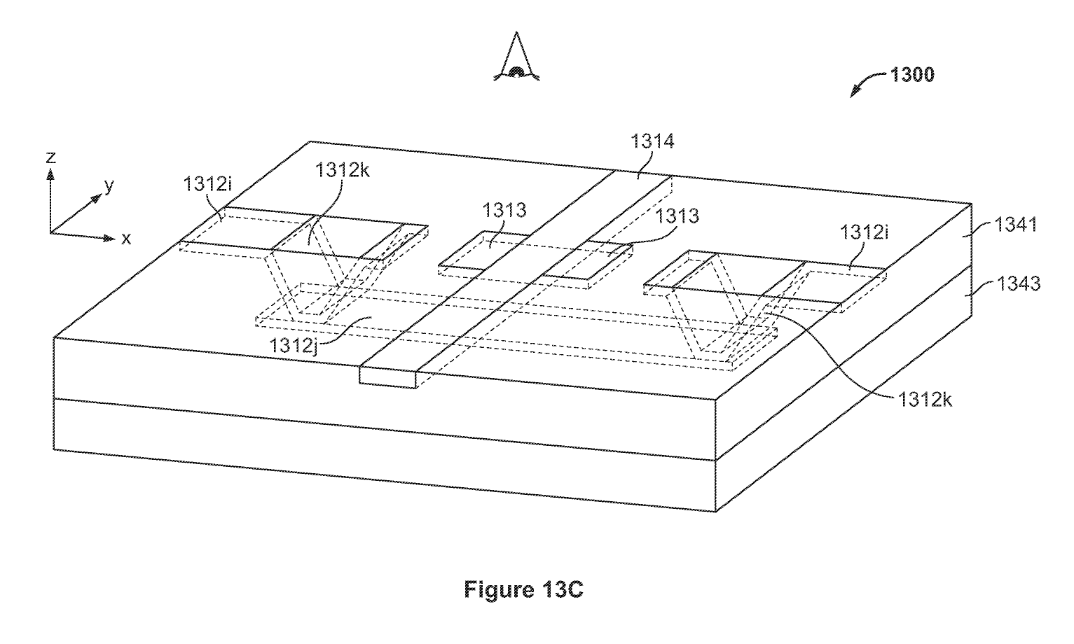

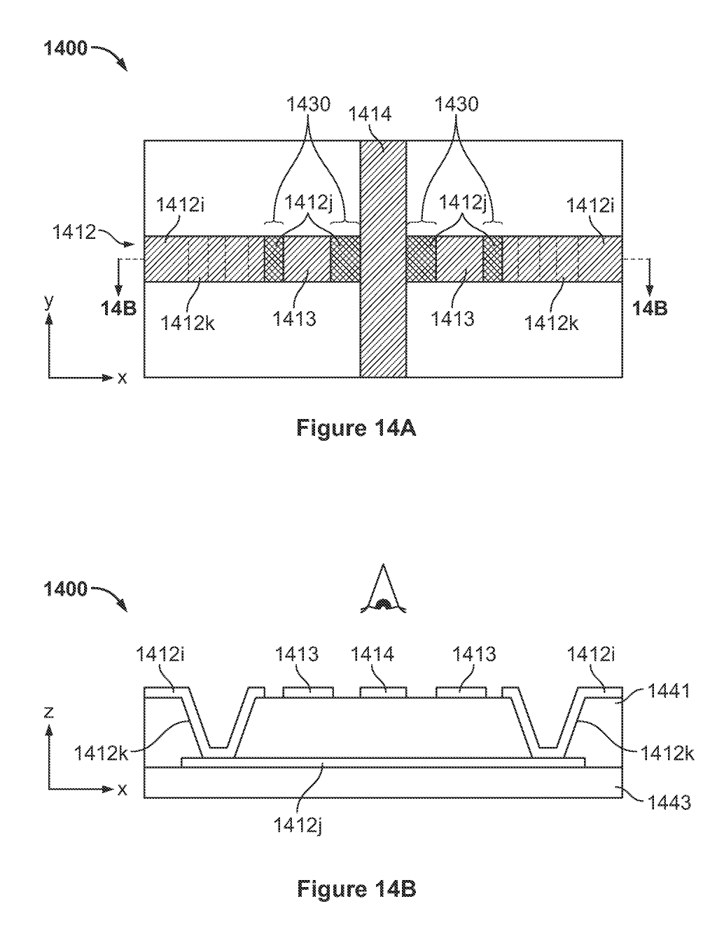

The light shielding structures 1213 shown in FIGS. 12A-12C as extending from the connection portions 1212k of the row electrodes 1212 so as to be coplanar with the column electrode 1214 and the coplanar portions 1212i of the row electrodes 1212. However, in other implementations, the shielding portions 1213 may extend from the column electrodes 1214 or may be separate structures. Examples of these other implementations are schematically illustrated in FIG. 13A-14C and described below. Although it may be desirable to reduce the reflectance from the jumper portions 1212j, the sensor 1200 is formed without electrically coupling the column electrode 1214 to the row electrode 1212. Thus, in some implementations, a small portion 1230 of the jumper portion 1212j may remain unshielded and reflect visible light toward a user or viewer.

FIG. 13A shows a top view of an example of an intersection of a PCT sensor 1300 with light shielding structures 1313 coupled to the column electrode 1314.

FIG. 13B shows a cross-sectional view of the intersection of the PCT sensor 1300 of FIG. 13A taken along line 13B-13B. FIG. 13C shows a top perspective view of the intersection of the PCT sensor 1300 of FIG. 13A. In the implementation illustrated in FIGS. 13A-13C, the light shielding structures 1313 are electrically coupled to the column electrode 1314 and electrically isolated from the row electrode 1312. As a result, as shown in FIG. 13A, the light shielding structures 1313 are disposed between the exposed jumper portions 1330 and the column electrode 1314. In this implementation, the inherent capacitance of the intersection is increased as compared to the implementation illustrated in FIG. 12 because the area of the column electrode 1314 and light shielding structures 1313 that overlies the row electrode 1312 is greater than the area of the column electrode that overlies the row electrode in FIG. 12.

FIG. 14A shows a top view of an example of an intersection of a PCT sensor 1400 with light shielding structures 1414 uncoupled from both the row electrode 1412 and the column electrode 1414. FIG. 14B shows a cross-sectional view of the intersection of the PCT sensor 1400 of FIG. 14A taken along line 14B-14B. FIG. 14C shows a top perspective view of the intersection of the PCT sensor 1400 of FIG. 14A. In the implementation illustrated in FIGS. 14A-14C, the light shielding structures 1413 are electrically isolated from both the row electrode 1412 and the column electrode 1414. As a result, as shown in FIG. 14A, light shielding structures 1413 are disposed between exposed jumper portions 1430.

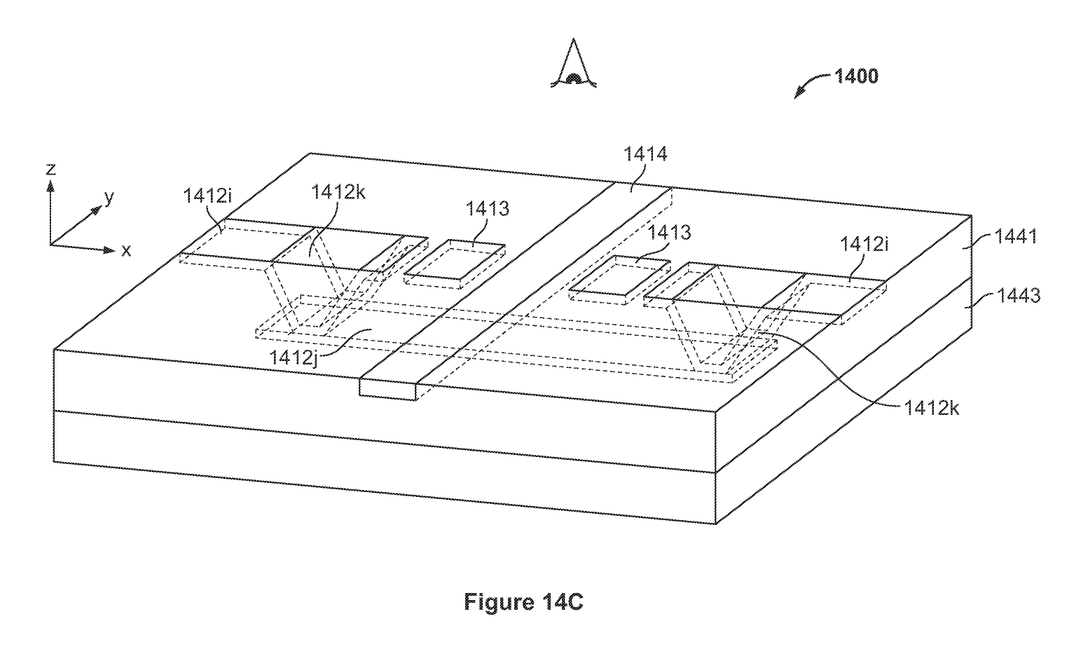

FIG. 15 shows an example of a cross-section of an interferometric stack that absorbs visible light. The interferometric stack 1500 can be disposed over a portion of a sensor electrode, e.g., coplanar portions of a row electrode and/or a column electrode, to limit a reflectance of visible light therefrom. Thus, in some implementations where a sensor electrode is at least partially non-transparent, the interferometric stack 1500 can be disposed over the sensor electrode to limit the reflectance therefrom. Further, in some implementations, the interferometric stack 1500 can form at least part of a light shielding structure. The interferometric stack 1500 can include an absorber layer 1510, a spacer layer 1520, and a reflective layer 1530. The spacer layer 1520 can be formed between the absorber layer 1510 and the reflective layer 1530.

In some implementations, light 1540 which strikes the absorber layer 1510 is substantially absorbed. However, a portion of the light 1540 is reflected by the absorber layer 1510 and another portion of the light 1540 is transmitted through the absorber layer 1510. The portion of the light 1540 that is transmitted through the absorber layer 1510 propagates through the spacer layer 1520 and is reflected by the reflective layer 1530 back through the transparent layer 1520 to the absorber layer 1510. The absorber layer 1510 substantially absorbs the reflected light. However, a portion of the reflected light is transmitted through the absorber layer 1510. The portion of the light 1540 that is reflected by the absorber layer 1510 and the portion of the reflected light that is transmitted through the absorber layer 1510 add together and optically interfere with each other such that visible wavelengths of light are cancelled and non-visible wavelengths of light (e.g., infrared wavelengths or ultraviolet wavelengths) are enhanced. Thus, in general, incident light 1540 upon the interferometric stack 1500 is either absorbed by the absorber layer 1510 or interferometrically modulated to non-visible wavelengths.

Suitable materials for the reflective layer 1530 can include molybdenum (Mo) and/or aluminum (Al). The reflective layer 1530 can be of a sufficient thickness to substantially reflect visible light. In some implementations, the reflective layer 1530 can be a molybdenum (Mo) layer of approximately 500 Angstroms. In some implementations, the spacer layer 1520 is made from a transparent conductive material, such as indium tin oxide (ITO), zinc oxide (ZnO), indium gallium zinc oxide (InGaZnO), etc. In some other implementations, the spacer layer 1520 is made from a transparent insulating material, such as silicon dioxide (SiO₂). The spacer layer 1520 can be of a sufficient thickness to form an interferometric cavity between the absorber layer 1510 and reflective layer 1530 that interferometrically modulates light to non-visible wavelengths. In some implementations, the spacer layer 1520 can be a layer of approximately 450 Angstroms. Suitable materials for the absorber layer 1510 can include molychrome (MoCr). The absorber layer 1510 can be of a sufficient thickness to substantially absorb light. In some implementations, the absorber layer 1510 can be a molychrome (MoCr) layer of approximately 50 Angstroms. As discussed above with reference to FIG. 1, the materials and dimensions of the absorber layer 1510, the spacer layer 1520, and the reflective layer 1530 can be selected so as to interferometrically modulate light that is incident on the stack 1500 to limit a reflectance of visible light therefrom. For example, in some implementations, the interferometric stack 1500 can be configured similar to the black mask 23 discussed above with reference to FIG. 6D.

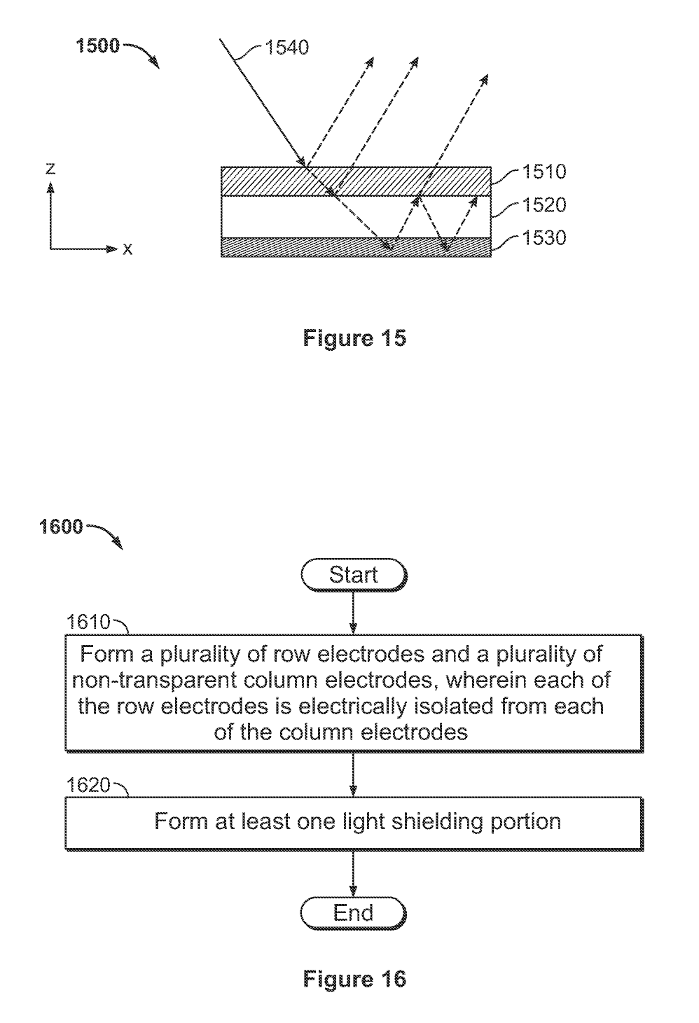

FIG. 16 shows an example of a flow diagram illustrating a manufacturing process for a PCT sensor. The process 1600 begins in block 1610 with the formation of a plurality of row electrodes and a plurality of non-transparent column electrodes. Each of the row electrodes are electrically isolated form each of the column electrodes. At least one of the plurality of row electrodes includes a first portion that is non-coplanar with at least one of the column electrodes and a second portion that is non-transparent and non-coplanar with the first portion. Such row electrodes and column electrodes are illustrated in FIGS. 9, 10, and 11. The process continues to block 1620 with the formation of at least one light shielding structure. The at least one light shielding structure overlies at least a portion of the first portion. As process 1600 is just one example of a flow diagram illustrated a manufacturing process for a PCT sensor, in some implementations, the array can be formed before, after, or while the light shielding structures are formed. For example, the light shielding structures may be formed simultaneously with the column electrodes and the second portion of the row electrodes. In some implementations, the portion of the row electrode that is non-planar with the column electrodes is a metallic jumper. The light shielding structures may reduce the amount of light that reaches the metallic jumpers and may further reduce that amount of light which would reflect off the metallic jumpers into the eyes of a viewer. Hence, interference with the viewing of a display beneath the touch sensor can be reduced.

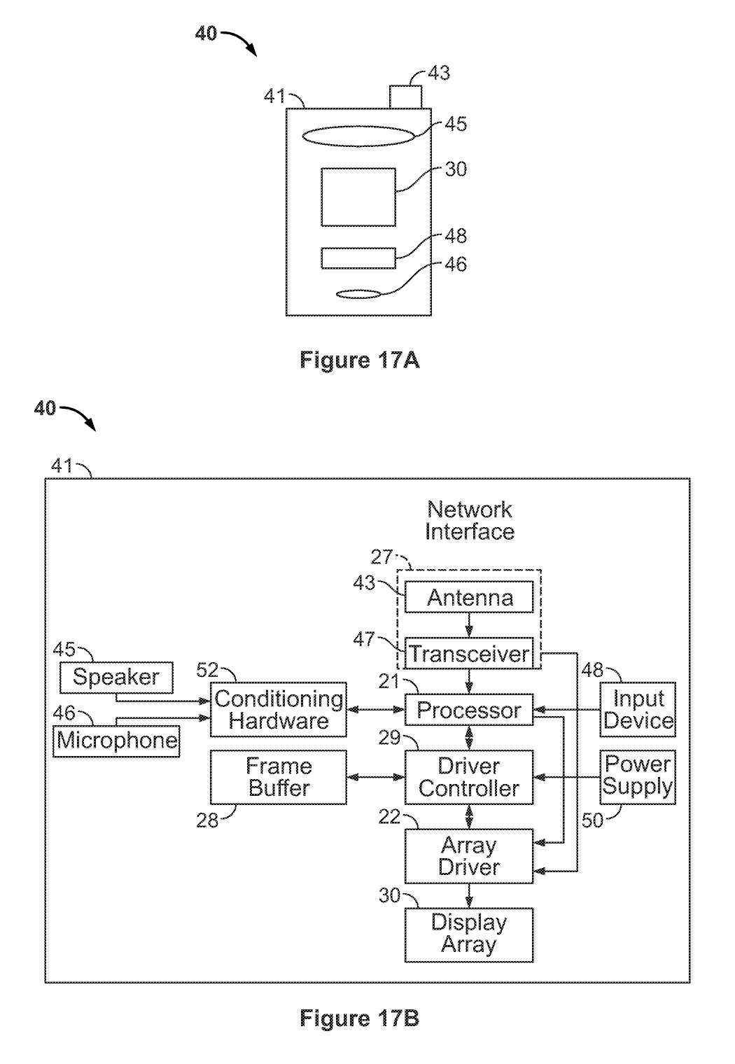

FIGS. 17A and 17B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 17B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1×EV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

If implemented in software, the functions may be stored on or transmitted over as one or more instructions or code on a computer-readable medium. The steps of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Disk and disc, as used herein, includes compact disc (CD), laser disc, optical disc, digital versatile disc (DVD), floppy disk, and blu-ray disc where disks usually reproduce data magnetically, while discs reproduce data optically with lasers. Combinations of the above should also be included within the scope of computer-readable media. Additionally, the operations of a method or algorithm may reside as one or any combination or set of codes and instructions on a machine readable medium and computer-readable medium, which may be incorporated into a computer program product.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A device comprising:
a plurality of non-transparent column electrodes;
a plurality of row electrodes, each of the row electrodes being electrically isolated from each of the column electrodes, at least one of the plurality of row electrodes including:
a first portion, wherein the first portion of the at least one row electrode is non-coplanar with at least one of the column electrodes; and
a second portion, wherein the second portion of the at least one row electrode is non-transparent and non-coplanar with the first portion; and
at least one light shielding structure, wherein the at least one light shielding structure overlies at least a portion of the first portion.

2. The device of claim 1, wherein the second portion is non-coplanar with at least one of the plurality of column electrodes.

3. The device of claim 1, wherein the at least one light shielding structure is coplanar with the first portion of the at least one row electrode.

4. The device of claim 1, wherein the plurality of row electrodes and the plurality of column electrodes extend generally perpendicular to one another.

5. The device of claim 1, wherein the at least one light shielding structure extends generally parallel to the at least one row electrode.

6. The device of claim 1, wherein the at least one light shielding structure is electrically isolated from the plurality of row electrodes.

7. The device of claim 1, wherein the at least one light shielding structure is electrically isolated from the plurality of column electrodes.

8. The device of claim 1, wherein the at least one light shielding structure includes a reflective layer, an absorber layer, and a spacer layer located between the reflective layer and the absorber layer.

9. The device of claim 8, wherein the spacer layer includes a conductive material.

10. The device of claim 8, wherein the spacer layer includes a dielectric material.

11. The device of claim 1, further comprising a processor configured to apply one or more voltages to a set of row electrodes and measure one or more voltages at a set of column electrodes.

12. The device of claim 11, wherein the processor is further configured to determine one or more touch locations based on the measured one or more voltages.

13. The device of claim 1, wherein the at least one column electrode overlies the first portion of the at least one row electrode at an intersection.

14. The device of claim 1, wherein an exposed portion of the first portion is less than 25 percent of the first portion as a whole.

15. The device of claim 14, wherein the at least one light shielding structure overlies the first portion as to prevent the first portion from being visible to a naked eye.

16. The device of claim 14, wherein the at least one light shielding structure overlies the first portion as to prevent the first portion from interfering with viewing images displayed by a screen behind the array.

17. The device of claim 1, wherein the first portion is transparent.

18. A method of manufacturing a device, the method comprising:
forming a plurality of row electrodes and a plurality of non-transparent column electrodes, wherein each of the row electrodes is electrically isolated from each of the column electrodes, at least one of the plurality of row electrodes including:
a first portion, wherein the first portion of the at least one row electrode is non-coplanar with at least one of the column electrodes; and
a second portion, wherein the second portion of the at least one row electrode is non-transparent and non-coplanar with the first portion; and
forming at least one light shielding structure, wherein the at least one light shielding structure overlies at least a portion of the first portion.

19. The method of claim 18, further comprising coupling a processor to a set of row electrodes and to a set of column electrodes, wherein the processor is configured to apply one or more voltages to the set of row electrodes and measure one or more voltages at the set of column electrodes.

20. The method of claim 19, wherein the processor is further configured to determine one or more touch locations based on the measured one or more voltages.

21. The method of claim 18, wherein forming the at least one light shielding structure includes forming a reflective layer, an absorber layer, and a spacer layer between the reflective layer and the absorber layer.

22. The method of claim 18, wherein an exposed portion of the first portion is less than 25 percent of the first portion as a whole.

23. The method of claim 22, wherein the at least one light shielding structure overlies the first portion as to prevent the first portion from interfering with viewing images displayed by a screen behind the array.

24. A device comprising:
a plurality of non-transparent column electrodes;
a plurality of row electrodes, each of the row electrodes being electrically isolated from each of the column electrodes, at least one of the plurality of row electrodes including:
a first portion, wherein the first portion of the at least one row electrode is non-coplanar with at least one of the column electrodes; and
a second portion, wherein the second portion of the at least one row electrode is non-transparent and non-coplanar with the first portion; and
means for shielding light from the first portion.

25. The device of claim 24, wherein the means for shielding light include a reflective layer, an absorber layer, and a spacer layer located between the reflective layer and the absorber layer.

26. The device of claim 24, wherein the spacer layer includes a conductive material.

27. The device of claim 24, wherein the spacer layer includes a dielectric material.

28. The device of claim 24, wherein the means for shielding light include an absorber.

29. The device of claim 24, further comprising a processor configured to apply one or more voltages to a set of row electrodes and measure one or more voltages at a set of column electrodes.

30. The device of claim 29, wherein the processor is further configured to determine one or more touch locations based on the measured one or more voltages.

31. The device of claim 24, wherein the at least one column electrode overlies the first portion of the at least one row electrode at an intersection.

32. The device of claim 24, wherein an exposed portion of the first portion is less than 25 percent of the first portion as a whole.

33. The device of claim 32, wherein the means for shielding light overlie the first portion as to prevent the first portion from being visible to a naked eye.

34. The device of claim 32, wherein the means for shielding light overlie the first portion as to prevent the first portion from interfering with viewing images displayed by a screen behind the array.
